(19) United States
(12) Patent Application Publication
(10) Pub. No.: US 2025/0393371 A1
(43) Pub. Date: Dec. 25, 2025

(54) DISPLAY MODULE AND ELECTRONIC DEVICE

(71) Applicant: SAMSUNG ELECTRONICS CO., LTD., Suwon-si (KR)

(72) Inventors: Youngmok PARK, Suwon-si (KR); Jonghoon JUNG, Suwon-si (KR); Jinyoung KIM, Suwon-si (KR); Sungyong MIN, Suwon-si (KR)

(73) Assignee: SAMSUNG ELECTRONICS CO., LTD., Suwon-si (KR)

(21) Appl. No.: 19/265,782

(22) Filed: Jul. 10, 2025

Related U.S. Application Data
(63) Continuation of application No. PCT/KR2025/005488, filed on Apr. 23, 2025.

(30) Foreign Application Priority Data
Jun. 19, 2024 (KR) 10-2024-0079609

(51) Int. Cl. H10H 29/80; H01L 21/68; H01L 25/075

(52) U.S. Cl. CPC H10H 29/8421; H01L 25/0753; H10H 29/832; H01L 21/68

(57) ABSTRACT

A display may include: a circuit board including a first drive electrode and a second drive electrode; and a light-emitting diodes (LED) including: semiconductor layers stacked in a horizontal direction parallel to a surface of the circuit board, the semiconductor layers including: an n-type semiconductor layer; a light-emitting layer; and a p-type semiconductor layer; a first pixel electrode in contact with the first drive electrode; and a second pixel electrode in contact with the second drive electrode.

### CROSS-REFERENCE TO RELATED APPLICATION

This application is a bypass continuation of International Application No. PCT/PCT/KR2025/005488, filed on Apr. 23, 2025, which is based on and claims priority to Korean Patent Application No. 10-2024-0079609, filed on Jun. 19, 2024, in the Korean Intellectual Property Office, the disclosures of which are incorporated by reference herein in their entireties.

### BACKGROUND

### 1. Field

The present disclosure relates to a display module and an electronic device, and more particularly, to a display module that may increase space efficiency and luminous efficiency and an electronic device including the display module.

### 2. Description of Related Art

In recent years, technology for a light emitting diode (LED) based on a compound semiconductor such as gallium nitride (GaN), gallium arsenide (GaAs), and gallium phosphide (GaP) has been developing rapidly, and there is growing interest in an LED display device that uses panel configuration technology for directly mounting (transferring) the LEDs that emit light in red (R), green (G), and blue (B) wavelength bands onto a circuit board.

In particular, the LED display device necessarily requires the LED to be miniaturized to output a high-quality image, and a lot of development infrastructures have been invested to perfect an ultra-small micro-LED of less than 100 micrometers. Furthermore, a process for precisely mounting the ultra-small LED of tens of micrometers has been developed recently, thus requiring LED and module manufacturing technology optimized for this process.

As a related art technology, there exists a technology that uses a flip-chip type LED. However, this technology has difficulty in effectively using light emitted toward a lower part of the LED because a significant portion of a lower area of the LED is covered by a pixel electrode.

Meanwhile, as another related art technology, there exists a technology that uses a vertical type LED in which the pixel electrode is disposed on each of upper and lower parts of the LED. However, this technology requires the use of an upper connection layer, such as indium tin oxide (ITO), or a separate wire to connect the upper electrode of the LED to the circuit board, which may cause the complexity of its design and process, leading to not only low space efficiency but also reduced luminous efficiency.

### SUMMARY

Provided are a display module having high space efficiency and high luminous efficiency, and a method of manufacturing such a display module and an electronic device including the display module.

According to an aspect of the disclosure, a display may include: a circuit board including a first drive electrode and a second drive electrode; and a light-emitting diodes (LED) including: semiconductor layers stacked in a horizontal direction parallel to a surface of the circuit board, the semiconductor layers including: an n-type semiconductor layer; a light-emitting layer; and a p-type semiconductor layer; a first pixel electrode in contact with the first drive electrode; and a second pixel electrode in contact with the second drive electrode.

The LED may further include: a light-emitting surface parallel to the surface of the circuit board; and reflective layers on at least two of four side surfaces of the LED and perpendicular to the light-emitting surface.

The first pixel electrode and the second pixel electrode may be on two first side surfaces parallel to the semiconductor layers among the four side surfaces, and the reflective layers may be on two second side surfaces perpendicular to the semiconductor layers among the four side surfaces.

The reflective layers may be on the four side surfaces and on a lower surface of the LED.

The LED further may further include an insulating layer on a lower surface of the LED.

The first pixel electrode and the second pixel electrode may be in contact with portions of lower regions of the two first side surfaces.

The first pixel electrode and the second pixel electrode may contact two of vertices of a square corresponding to one of the two second side surfaces.

An area of an upper surface of the LED corresponding to a light-emitting surface may be greater than an area of a lower surface of the LED.

According to an aspect of the disclosure, a light-emitting diode (LED) may include: a light-emitting surface; a light-emitting layer; a p-type semiconductor layer stacked on a first side of the light-emitting layer in a direction parallel to the light-emitting surface; an n-type semiconductor layer stacked on a second side opposite the first side of the light-emitting layer in the direction parallel to the light-emitting surface; a first pixel electrode connected to the p-type semiconductor layer; and a second pixel electrode connected to the n-type semiconductor layer.

The LED may further include reflective layers on at least two of four side surfaces of the LED and perpendicular to the light-emitting surface.

The first pixel electrode and the second pixel electrode may be on two first side surfaces parallel to the light-emitting layer among the four side surfaces. The reflective layers may be on two second side surfaces perpendicular to the light-emitting layer among the four side surfaces.

The reflective layers may be on the four side surfaces and on a lower surface of the LED.

The LED may further include an insulating layer on a lower surface of the LED.

The first pixel electrode and the second pixel electrode may be in contact with portions of lower regions of the two first side surfaces.

The first pixel electrode and the second pixel electrode may contact two of vertices of a square corresponding one of the two second side surfaces.

An area of an upper surface of the LED corresponding to the light-emitting surface may be greater than an area of a lower surface of the LED.

The display may further include a plurality of the LED.

According to one or more embodiments of the present disclosure, a method of manufacturing a display module includes: forming a plurality of light-emitting diodes (LEDs) on a wafer, each including a plurality of semiconductor layers and two pixel electrodes disposed on an upper part of the plurality of semiconductor layers and a lower part of the plurality of semiconductor layers; disposing a plurality of protrusions included in an aligner between the plurality of LEDs; and moving the aligner in a horizontal direction to rotate the plurality of LEDs by 90 degrees on the wafer by the plurality of protrusions.

The method may further include: forming a bump on each of the two pixel electrodes; transferring the plurality of LEDs to a circuit board including a plurality of drive electrodes; and connecting the plurality of drive electrodes to the two pixel electrodes using the bumps.

The method may further include: forming a plurality of reflective layers on at least some of four surfaces perpendicular to a light-emitting surface of each of the plurality of LEDs; and forming a black matrix between the plurality of LEDs.

The transferring of the plurality of LEDs may include transferring the plurality of LEDs to a motherboard to allow a red LED, a green LED, and a blue LED among the plurality of LEDs to be included in one pixel, and transferring the plurality of LEDs transferred to the motherboard to the circuit board.

### BRIEF DESCRIPTION OF THE DRAWINGS

The above and other aspects, features, and advantages of certain embodiments of the present disclosure will be more apparent from the following description taken in conjunction with the accompanying drawings, in which:

FIG. 1 is a view showing a portion of a display module according to one or more embodiments of the present disclosure;

FIG. 2 is a view showing a portion of the display module according to one or more embodiments of the present disclosure;

FIG. 3 is a view showing one or more embodiments in which each of a plurality of light emitting diodes (LEDs) includes three reflective layers;

FIG. 4 is a view showing one or more embodiments in which each of a plurality of light emitting diodes (LEDs) includes three reflective layers;

FIG. 5 is a view showing one or more embodiments in which each of the plurality of LEDs includes five reflective layers;

FIG. 6 is a view showing one or more embodiments in which each of the plurality of LEDs includes five reflective layers;

FIG. 7 is a view showing one or more embodiments in which each of the plurality of LEDs includes two reflective layers and three insulating layers;

FIG. 8 is a view showing one or more embodiments in which each of the plurality of LEDs includes two reflective layers and three insulating layers;

FIG. 9 is a flowchart briefly showing a part of a method of manufacturing a display module according to one or more embodiments of the present disclosure;

FIG. 10 is a view specifically showing a part of the method of manufacturing a display module according to one or more embodiments of the present disclosure;

FIG. 11 is a flowchart briefly partially showing another part of the method of manufacturing a display module according to one or more embodiments of the present disclosure;

FIG. 12 is a view specifically showing another part of the method of manufacturing a display module according to one or more embodiments of the present disclosure; and

FIG. 13 is a view showing an electronic device including the display module according to the present disclosure.

### DETAILED DESCRIPTION

The present disclosure may be variously modified and have several embodiments, and specific embodiments of the present disclosure are thus shown in the drawings and described in detail in the detailed description. However, it should be understood that the scope of the present disclosure is not limited to the specific embodiments, and includes various modifications, equivalents, and/or alternatives according to the embodiments of the present disclosure. Throughout the accompanying drawings, similar components are denoted by similar reference numerals.

In describing the present disclosure, omitted is a detailed description of a case where it is decided that the detailed description of the known functions or configurations related to the present disclosure may unnecessarily obscure the gist of the present disclosure.

In addition, the following embodiments may be modified in several different forms, and the scope and spirit of the present disclosure are not limited to the following embodiments. Rather, these embodiments are provided to make the present disclosure thorough and complete, and completely transfer the spirit of the present disclosure to those skilled in the art.

Terms used in the present disclosure are used only to describe the specific embodiments rather than limit the scope of the present disclosure. A term of a singular number includes its plural number unless explicitly interpreted otherwise in the context.

In the present disclosure, an expression “have”, “may have”, “include”, “may include”, or the like, indicates the presence of a corresponding feature (for example, a numerical value, a function, an operation, or a component such as a part), and does not exclude the presence of an additional feature.

In the present disclosure, an expression “A or B”, “at least one of A and/or B”, “one or more of A and/or B”, or the like, may include all possible combinations of items enumerated together. For example, “A or B”, “at least one of A and B”, or “at least one of A or B” may indicates all of 1) a case where at least one A is included, 2) a case where at least one B is included, or 3) a case where both of at least one A and at least one B are included.

Expressions “first”, “second”, and the like used in the present disclosure, may indicate various components regardless of the sequence and/or importance of the components. These expressions are used only to distinguish one component and another component from each other, and do not limit the corresponding components.

If any component (for example, a first component) is mentioned to be “(operatively or communicatively) coupled with/to” or “connected to” another component (for example, a second component), it should be understood that any component is directly coupled to another component or may be coupled to another component through yet another component (for example, a third component).

On the other hand, if any component (for example, the first component) is mentioned to be “directly coupled” or “directly connected to” another component (for example, the second component), it should be understood that yet another component (for example, the third component) is not present between any component and another component.

An expression “configured (or set) to” used in the present disclosure may be replaced with an expression “suitable for”, “having the capacity to”, “designed to”, “adapted to”, “made to”, or “capable of” based on a context. The expression “configured (or set) to” may not necessarily indicate “specifically designed to” in hardware.

Rather, an expression “a device configured to” in some contexts may indicate that the device may “perform˜” together with another device or component. For example, “a processor configured (or set) to perform A, B and C” may indicate a dedicated processor (for example, an embedded processor) that may perform the corresponding operations or a generic-purpose processor (for example, a central processing unit (CPU) or an application processor) that may perform the corresponding operations by executing one or more software programs stored in a memory device.

In the embodiments, a “module” or a “˜er/or” may perform at least one function or operation, and be implemented by hardware, software, or a combination of hardware and software. In addition, a plurality of “modules” or a plurality of “˜ers/ors” may be integrated with each other in at least one module and implemented by at least one processor except for a “module” or an “˜er/or” that needs to be implemented in specific hardware.

In the specification, spatially relative terms such as “top”, “bottom”, “upper”, “lower”, “up”, “down”, “horizontal,” “vertical” etc. are used to easily explain the positional relationship of each component when viewed from a direction depicted in the drawings. Therefore, spatially relative terms indicating the positional relationship of each component may be understood differently when viewed from a direction other than the direction depicted in the drawings.

Meanwhile, various elements and regions in the drawings are schematically shown. Therefore, the spirit of the present disclosure is not limited to relative sizes or intervals shown in the accompanying drawings.

Hereinafter, the embodiments of the present disclosure are described in detail with reference to the accompanying drawings so that those skilled in the art to which the present disclosure pertains may easily practice the present disclosure.

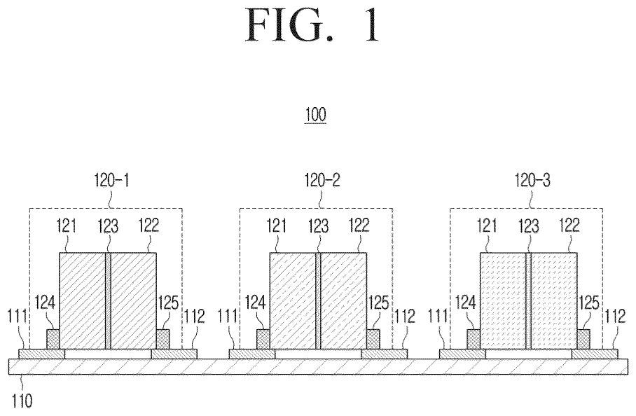

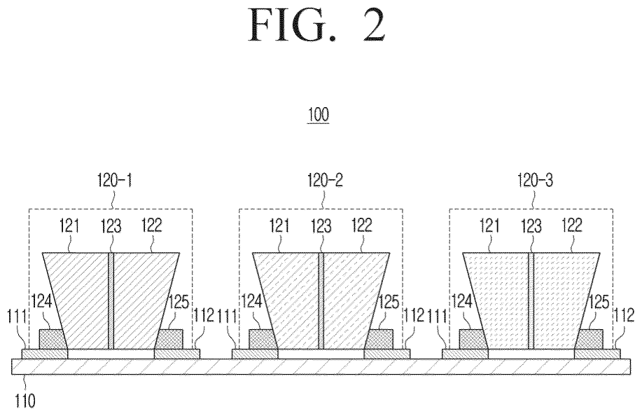

FIG. 1 is a view showing a portion of a display module 100 according to one or more embodiments of the present disclosure. In addition, FIG. 2 is a view showing a portion of the display module 100 according to one or more embodiments of the present disclosure.

FIGS. 1 and 2 differ only in shapes of a light emitting diode (LED) 120 and a pixel electrode, and the description is provided below with reference to FIGS. 1 and 2 together. Hereinafter, the description first describes the basic structure and operation of each component included in the display module 100, and then describes the various embodiments of the present disclosure with specific reference to FIGS. 1 and 2.

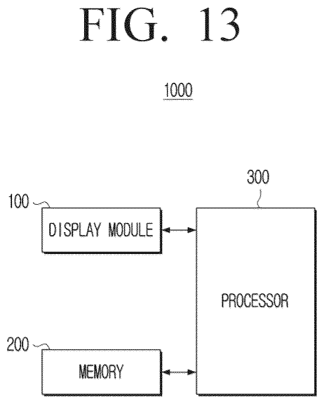

The “display module 100” (display) according to the present disclosure refers to a component (or device) capable of displaying an image. In particular, the display module 100 may be included in the electronic device 1000 to display an image. If the display module 100 is included in the electronic device 1000, the display module 100 may display the image under control of a processor 300 included in the electronic device 1000. The electronic device 1000 including the display module 100 is described with reference to FIG. 13, and the various embodiments related to the display module 100 are described below.

The display module 100 may indicate an entire display panel included in the electronic device 1000, and the plurality of display modules 100 may be coupled to form a single display panel. That is, the display module 100 may be included in the electronic device 1000 of a type such as a digital television (TV), a monitor, a tablet personal computer (PC), or a smartphone, and also may be included in the electronic device 1000 of a type such as a digital signage or a video wall. However, there is no particular limitation on the type of electronic device 1000 using the display module 100 according to the present disclosure.

As shown in FIGS. 1 and 2, the display module 100 may include a circuit board 110 and a plurality of LEDs 120. FIGS. 1 and 2 show a structure of the display module 100 including three LEDs 120, which is provided only for simplification of the drawing, and there is no particular limitation on the number of LEDs 120 included in the display module 100. Hereinafter, for convenience of description, the description first describes the plurality of LEDs 120.

The “plurality of LEDs 120” may emit light under control of the circuit board 110. In detail, the LED 120 refers to a device that emits light if a voltage is applied in a forward direction, and the term “LED 120” may indicate an “LED 120 chip” in which a chip-scale packaging process is completed for the LED 120.

Referring to FIGS. 1 and 2, each of the plurality of LEDs 120 according to the present disclosure may include a plurality of semiconductor layers and two pixel electrodes 124 and 125. In addition, the plurality of semiconductor layers may include an n-type semiconductor layer 122, a p-type semiconductor layer 121, and a light-emitting layer 123.

The n-type semiconductor layer 122 or the p-type semiconductor layer 121 may be implemented as a compound semiconductor of a group III-V, II-VI, or the like. In particular, the n-type semiconductor layer 122 or the p-type semiconductor layer 121 may be implemented as a nitride semiconductor. For example, the n-type semiconductor layer 122 and the p-type semiconductor layer 121 may be an n-GaN semiconductor layer and a p-GaN semiconductor layer, respectively. However, the n-type semiconductor layer 122 and the p-type semiconductor layer 121 according to the present disclosure are not limited thereto, and may be made of various materials based on various characteristics required for the LED 120.

The n-type semiconductor layer 122 is a semiconductor in which free electrons are used as carriers to transfer charges, and may be made by doping with n-type dopants such as silicon (Si), germanium (Ge), tin (Sn), and tellurium (Te). In addition, the p-type semiconductor is a semiconductor in which holes are used as the carriers to transfer the charges, and may be made by doping with p-type dopants such as magnesium (Mg), zinc (Zn), calcium (Ca), and barium (Ba).

The light-emitting layer 123, the n-type semiconductor layer 122, and the p-type semiconductor layer 121 may include various semiconductors having band gaps corresponding to specific regions in a spectrum. For example, the red LED 120 having a light wavelength of 600 to 750 nm may include at least one layer based on an aluminum indium gallium phosphide (AlInGaP) semiconductor. In addition, the blue LED 120 and the green LED 120, having light wavelengths of 450 to 490 nm and 500 to 570 nm, respectively, may each include at least one layer based on an aluminum indium gallium nitride (AlInGaN) semiconductor.

The light-emitting layer 123 may be disposed between the n-type semiconductor layer 122 and the p-type semiconductor layer 121, and may be a layer where the electrons, which are the carriers of the n-type semiconductor layer 122, and the holes, which are the carriers of the p-type semiconductor layer 121, meet each other. If the electrons and the holes meet each other in the light-emitting layer 123, a potential barrier may be formed as the electrons and the holes are recoupled to each other. In addition, if the electrons and holes move across the potential barrier to transition to a lower energy level based on the voltage applied thereto, the electrons and holes may emit light of a corresponding wavelength.

Here, the light-emitting layer 123 may be a multiple-quantum well structure. However, the present disclosure is not limited thereto, and the light-emitting layer 123 may have various structures such as a single-quantum well structure and a quantum dot structure. If the light-emitting layer 123 is formed to have the multi-quantum well structure, a well layer/barrier layer of the light-emitting layer 123 may be formed to have a structure such as indium gallium nitride/gallium nitride (InGaN/GaN), indium gallium nitride/indium gallium nitride (InGaN/InGaN), or gallium arsenide/aluminum gallium arsenide (GaAs/AlGaAs). However, the present disclosure is not limited to such a structure. In addition, the number of quantum wells included in the light-emitting layer 123 may not be limited to a specific number.

Three LEDs 120 shown in FIG. 1 or 2 represent a red LED 120-1, a green LED 120-2, and a blue LED 120-3, each included in one pixel. That is, the display module 100 may be classified into the plurality of pixels, and the red LED 120-1, the green LED 120-2 and the blue LED 120-3 may implement one pixel of the display module 100. However, there are no particular limitations on the number of LEDs 120 per pixel and their arrangement method according to the present disclosure.

The “two pixel electrodes 124 and 125” refer to electrodes included in each of the plurality of LEDs 120 to connect the plurality of LEDs 120 to the circuit board 110. In detail, the two pixel electrodes 124 and 125 may be connected to a plurality of drive electrodes 111 and 112 of the circuit board 110, thus connecting the plurality of LEDs 120 to the circuit board 110. In the present disclosure, the term “pixel electrode” is a term to distinguish the pixel electrode from the drive electrode disposed on the circuit board 110, and may be replaced with a term such as a “pixel electrode pad”.

The two pixel electrodes 124 and 125 may include the first pixel electrode 124 and the second pixel electrode 125. Here, the “first pixel electrode 124” refers to a pixel electrode connected to the p-type semiconductor layer 121 and the first drive electrode 111 of the circuit board 110, and the “second pixel electrode 125” refers to a pixel electrode connected to the n-type semiconductor layer 122 and the second drive electrode 112 and having an opposite polarity to that of the first pixel electrode 124.

Hereinabove, each of the plurality of LEDs 120 is described as including the two pixel electrodes 124 and 125, which is provided only for the convenience of description, and three or more pixel electrodes may be included in each of the plurality of LEDs 120.

The “circuit board 110” refers to a board including a drive circuit for driving the plurality of LEDs 120 and the plurality of drive electrodes 111 and 112. The term “circuit board 110” may be replaced with a term such as a “drive board”. The plurality of LEDs 120 may be disposed on the circuit board 110 and electrically connected to the drive circuit. The display module 100 may be driven using an active matrix manner or a passive matrix method, and the drive circuit may be designed to suit the drive method. The circuit board 110 may be one of a thin-film transistor (TFT) board, a printed circuit board, or a glass board including metal wiring, and is not limited thereto.

The drive circuit may be connected to the plurality of drive electrodes 111 and 112, and may include a plurality of circuit devices such as a switching device. The switching device is a semiconductor device that may control an operation of the plurality of LED devices 120 included in the display module 100, and serve as a kind of switch for an individual pixel of the display device. For example, a TFT may be used as the switching device.

The “plurality of drive electrodes 111 and 112” refer to electrodes included in the circuit board 110 to connect the plurality of LEDs 120 to the circuit board 110. The plurality of drive electrodes 111 and 112 may be formed on one surface of the circuit board 110 and connected to the drive circuit, and may be connected to the two pixel electrodes 124 and 125 included in the plurality of LEDs 120. That is, in the present disclosure, the term “drive electrode” is a term to specify the electrode included in the circuit board 110 in distinction from the pixel electrode included in the plurality of LEDs 120, and may be replaced with a term such as a “drive electrode pad”. Meanwhile, based on a description method, the plurality of drive electrodes 111 and 112 and the circuit board 110 may be classified as separate components, and the plurality of drive electrodes 111 and 112 may be described as being formed on the circuit board 110.

The plurality of drive electrodes 111 and 112 may include the plurality of first drive electrodes 111 and the plurality of second drive electrodes 112. Here, the “first drive electrode 111” refers to the drive electrode connected to the first pixel electrode 124, and the “second drive electrode 112” refers to the drive electrode connected to the second pixel electrode 125 and having the opposite polarity to that of the first drive electrode 111. For example, the first drive electrode 111 may be an anode and the second drive electrode 112 may be a cathode.

The plurality of first drive electrodes 111 and the plurality of second drive electrodes 112 may have the opposite polarities. For example, the plurality of first drive electrodes 111 may be the anodes and the plurality of second drive electrodes 112 may be the cathodes. On the other hand, the plurality of first drive electrodes 111 may be the cathodes and the plurality of second drive electrodes 112 may be the anodes.

Hereinafter, the various embodiments of the present disclosure are described with reference to FIGS. 1 and 2.

As shown in FIGS. 1 and 2, the plurality of semiconductor layers may be disposed in a vertical direction relative to the circuit board 110. In detail, the plurality of semiconductor layers may be disposed to be perpendicular to a plane corresponding to the circuit board 110, rather than parallel to the plane corresponding to the circuit board 110. Light-emitting surfaces of the plurality of LEDs 120 may be parallel to the plane corresponding to the circuit board 110, and the plurality of semiconductor layers may also be disposed in the vertical direction relative to the light-emitting surfaces of the plurality of LEDs 120. The plurality of semiconductor layers being disposed in the vertical direction relative to the circuit board 110 indicates that the n-type semiconductor layer 122, the light-emitting layer 123, and the p-type semiconductor layer 121, included in the plurality of semiconductor layers, are all disposed in the vertical direction relative to the circuit board 110. In other words, the semiconductor layers may be stacked in a horizontal direction parallel to a surface of the circuit board and/or a light-emitting surface of the LED.

Meanwhile, in the present disclosure, the n-type semiconductor layer 122 and the p-type semiconductor layer 121 being disposed in the vertical direction relative to the circuit board 110 indicates that each surface of the n-type semiconductor layer 122 and the p-type semiconductor layer 121, in contact with the light-emitting layer 123, is disposed in the vertical direction relative to the circuit board 110. Therefore, even if the plurality of LEDs 120 have a shape as shown in FIG. 2, the n-type semiconductor layer 122 and the p-type semiconductor layer 121 may be disposed in the vertical direction relative to the circuit board 110.

The n-type semiconductor layer 122, the light-emitting layer 123, and the p-type semiconductor layer 121 may be connected to one another in a horizontal direction. In detail, the n-type semiconductor layer 122, the light-emitting layer 123, and the p-type semiconductor layer 121 being all disposed in the vertical direction relative to the circuit board 110 indicates that the n-type semiconductor layer 122, the light-emitting layer 123, and the p-type semiconductor layer 121 are disposed to be parallel to one another. In addition, the light-emitting layer 123 may be disposed between the n-type semiconductor layer 122 and the p-type semiconductor layer 121, and the n-type semiconductor layer 122, the light-emitting layer 123, and the p-type semiconductor layer 121 may be connected to one another to be in contact with one another.

Each of the two pixel electrodes 124 and 125 may be disposed in an opposite direction relative to the light-emitting layer 123 to be connected to one of the plurality of drive electrodes 111 and 112. In detail, the first pixel electrode 124 may be disposed in a first direction relative to the light-emitting layer 123 to be connected to the first drive electrode 111 while being connected to the p-type semiconductor layer 121. The second pixel electrode 125 may be disposed in a second direction, which is opposite to the first direction, relative to the light-emitting layer 123, to be connected to the second drive electrode 112 while being connected to the n-type semiconductor layer 122.

Each of the plurality of LEDs 120 may include an upper surface corresponding to its light-emitting surface and a lower surface corresponding to its surface in an opposite direction of the light-emitting surface. In addition, each of the plurality of LEDs 120 may include four surfaces surrounding each of the plurality of LEDs 120 and perpendicular to the light-emitting surface of each of the plurality of LEDs 120. The four surfaces perpendicular to the light-emitting surface of each of the plurality of LEDs 120 may include two “first surfaces” parallel to the plurality of semiconductor layers and two “second surfaces” perpendicular to the plurality of semiconductor layers.

Each of the two pixel electrodes 124 and 125 may be disposed to be in contact with a portion of a lower region of the first surface. In more detail, the two pixel electrodes 124 and 125 may each be disposed in the region that includes two of vertices of a square corresponding to a side surface of each of the plurality of LEDs 120. As shown in FIGS. 1 and 2, the two pixel electrodes 124 and 125 may respectively be disposed at a lower left side of each of the plurality of LEDs 120 and at a lower right side of each of the plurality of LEDs 120. In this way, each of the two pixel electrodes 124 and 125 may be disposed in a corner region of a lower area of each of the plurality of LEDs 120, thereby connecting the plurality of semiconductor layers to the circuit board 110 without limiting the lower area of each of the plurality of LEDs 120.

There is no particular limitation on a shape of each of the plurality of LEDs 120 according to the present disclosure.

For example, as shown in FIG. 1, each cross-section of the plurality of LEDs 120 may be rectangular, that is, each of the plurality of LEDs 120 may have a rectangular parallelepiped shape. In other words, an area of the upper surface of each of the plurality of LEDs 120 corresponding to the light-emitting surface may be the same as an area of the lower surface of each of the plurality of LEDs 120. If each of the plurality of LEDs 120 is implemented to have the rectangular parallelepiped shape as in FIG. 1, there is no need to perform a separate etching process for the plurality of LEDs 120, thus significantly improving convenience of design and process.

In another example, as shown in FIG. 2, each of the plurality of LEDs 120 may have the cross-section formed in an inverted trapezoid (a trapezoid in which a length of an upper side is longer than a length of a lower side), that is, each of the plurality of LEDs 120 may have a trapezoidal column shape. In other words, the area of the upper surface of each of the plurality of LEDs 120 corresponding to the light-emitting surface may be the greater than that of the lower surface of each of the plurality of LEDs 120. Luminous efficiency of the plurality of LEDs 120 may be further improved if the area of the upper surface of each of the plurality of LEDs 120 corresponding to the light-emitting surface is implemented to be greater than that of the lower surface of each of the plurality of LEDs 120 as shown in FIG. 2.

According to the embodiments described above with reference to FIGS. 1 and 2, the display module 100 may provide the display module 100 having high space efficiency and high luminous efficiency.

In particular, unlike the related art vertical type LED 120, the display module 100 does not need to use an upper connection layer such as indium tin oxide (ITO) or a separate wire to connect an upper electrode of the LED 120 to the circuit board 110. Therefore, the display module 100 may have the high space efficiency and the high luminous efficiency, and further, may have low power consumption and convenience in design and process. In addition, the display module 100 may minimize the lower area of the LED 120 being covered by the pixel electrode, unlike the related art flip-chip type LED 120. Therefore, the display module 100 may effectively use light emitted toward a lower part of the LED 120, thereby further improving the luminous efficiency.

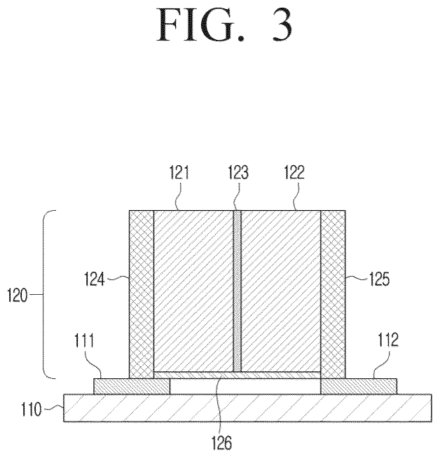

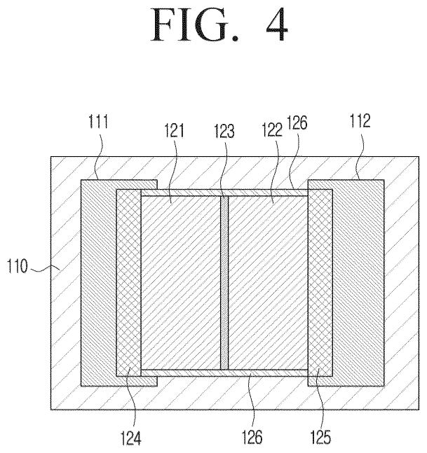

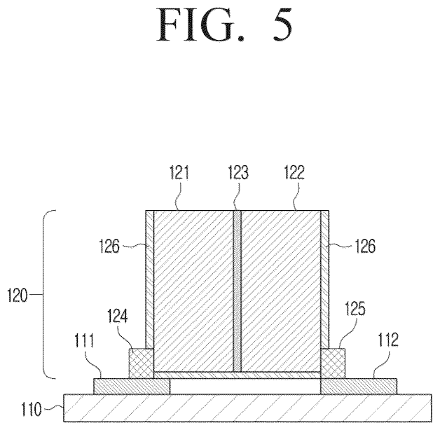

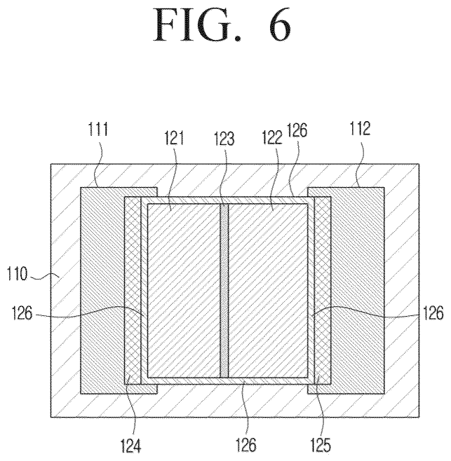

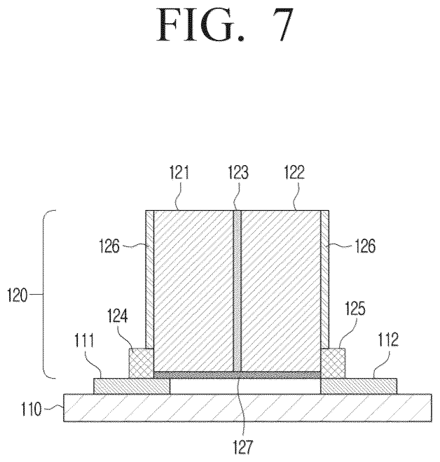

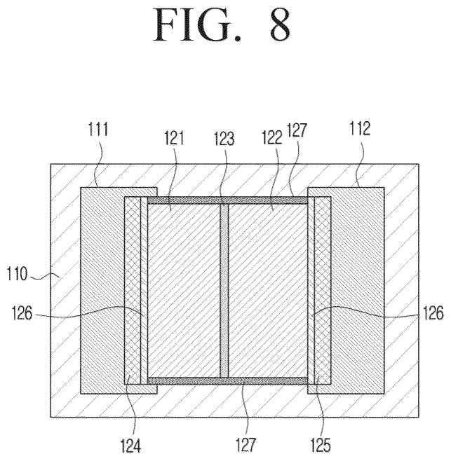

FIGS. 3 and 4 are views each showing one or more embodiments in which each of the plurality of LEDs 120 includes three reflective layers 126. FIGS. 5 and 6 are views each showing one or more embodiments in which each of the plurality of LEDs 120 includes five reflective layers 126. In addition, FIGS. 7 and 8 are views each showing one or more embodiments in which each of the plurality of LEDs includes two reflective layers 126 and three insulating layers 127.

FIGS. 3 to 8 show only one LED 120 and a portion of the circuit board 110 connected to one LED 120, which is provided only for convenience of illustration, and the present disclosure may also be applied to the display module 100 in which one LED 120 shown in FIGS. 3 to 8 is disposed in multiples on the entire circuit board 110.

As described above, each of the plurality of LEDs 120 may include the upper surface corresponding to its light-emitting surface and the lower surface corresponding to its surface in the opposite direction of the light-emitting surface. In addition, each of the plurality of LEDs 120 may include the four surfaces surrounding each of the plurality of LEDs 120 and perpendicular to the light-emitting surface of each of the plurality of LEDs 120. The four surfaces perpendicular to the light-emitting surface of each of the plurality of LEDs 120 may include the two “first surfaces” parallel to the plurality of semiconductor layers and the two “second surfaces” perpendicular to the plurality of semiconductor layers.

To show the six faces of the plurality of LEDs 120, FIG. 4 shows the structure of FIG. 3 in a top view, FIG. 6 shows the structure of FIG. 5 in a top view, and FIG. 8 shows the structure of FIG. 7 in a top view.

As shown in FIGS. 3 to 8, each of the plurality of LEDs 120 may further include the reflective layer 126. In addition, each of the plurality of LEDs 120 may further include the insulating layer 127. In addition, each of the plurality of LEDs 120 may further include various components to enhance the characteristics of the plurality of LEDs 120.

The reflective layer 126 may serve to increase the luminous efficiency of the LED 120 by reflecting light emitted from the light-emitting layer 123 of the LED 120 toward light-emitting surface of the LED device 120. For example, the reflective layer 126 may be formed as a metal reflector structure or a distributed-bragg-reflector structure.

The insulating layer 127 may stabilize the device characteristics of the plurality of LEDs 120. In particular, the insulating layer 127 may stabilize the device characteristics of the LED 120 by preventing light emitted from the light-emitting layer 123 from being emitted outside the LED 120. For example, the insulating layer 127 may include a material having excellent electrical insulation properties, such as silicon dioxide (SiO₂).

In one or more embodiments, each of the plurality of LEDs 120 may further include the plurality of reflective layers 126 disposed on at least some of the four surfaces surrounding each of the plurality of LEDs 120 and perpendicular to the light-emitting surface of each of the plurality of LEDs 120.

In detail, the plurality of reflective layers 126 may be disposed on the two first surfaces parallel to the plurality of semiconductor layers among the four surfaces perpendicular to the light-emitting surface of each of the plurality of LEDs 120. In this case, the reflective layers 126 or the insulating layer 127 may be disposed on the two second surfaces perpendicular to the plurality of semiconductor layers among the four surfaces perpendicular to the light-emitting surface of each of the plurality of LEDs 120 and on the lower surface of each of the plurality of LEDs 120.

In particular, the plurality of reflective layers 126 may be disposed on the two first surfaces parallel to the light-emitting layer 123 to improve the luminous efficiency. Therefore, the description of the present disclosure uses the expression “the plurality of reflective layers 126”, assuming that at least two reflective layers 126 are disposed, which does not exclude the possibility that each of the plurality of LEDs 120 includes only one reflective layer 126.

Meanwhile, instead of the reflective layer 126, the two pixel electrodes 124 and 125 may respectively be disposed on the two first surfaces parallel to the plurality of semiconductor layers among the four surfaces perpendicular to the light-emitting surface of each of the plurality of LEDs 120. In other words, instead of the separate reflective layer 126, the two pixel electrodes 124 and 125 may be disposed to cover the two first surfaces that are parallel to the plurality of semiconductor layers, thus allowing the two pixel electrodes 124 and 125 to perform even a function of the reflective layer 126. Therefore, in this case, each material of the two pixel electrodes 124 and 125 needs to be selected from a material having both electrical properties and high reflectivity, such as aluminum (Al) or silver (Ag). Meanwhile, in this case, the reflective layers 126 or the insulating layer 127 may be disposed on the two second surfaces perpendicular to the plurality of semiconductor layers among the four surfaces perpendicular to the light-emitting surface of each of the plurality of LEDs 120 and on the lower surface of each of the plurality of LEDs 120.

Referring to examples shown in FIGS. 3 and 4, the two pixel electrodes 124 and 125 may be disposed on the two first surfaces parallel to the plurality of semiconductor layers among the four surfaces perpendicular to the light-emitting surface of each of the plurality of LEDs 120. In addition, the plurality of reflective layers 126 may be disposed on the two second surfaces perpendicular to the plurality of semiconductor layers among the four surfaces perpendicular to the light-emitting surface of each of the plurality of LEDs 120 and on the lower surface of each of the plurality of LEDs 120.

Referring to examples shown in FIGS. 5 and 6, the plurality of reflective layers 126 may be disposed on the four surfaces perpendicular to the light-emitting surface of each of the plurality of LEDs 120 and on the lower surface of each of the plurality of LEDs 120. In other words, the plurality of reflective layers 126 may be disposed to surround all the surfaces of each of the plurality of LEDs 120 except its light-emitting surface.

Referring to examples shown in FIGS. 7 and 8, the plurality of reflective layers 126 may be disposed on the two first surfaces parallel to the plurality of semiconductor layers among the four surfaces perpendicular to the light-emitting surface of each of the plurality of LEDs 120. In addition, the insulating layers 127 may be disposed on the two second surfaces perpendicular to the plurality of semiconductor layers among the four surfaces perpendicular to the light-emitting surface of each of the plurality of LEDs 120 and on the lower surface of each of the plurality of LEDs 120.

In addition to the embodiments described above, the two pixel electrodes 124 and 125, the reflective layer 126, and the insulating layer 127 may be disposed on the side surface of each of the plurality of LEDs 120 in various ways except for its light-emitting surface, and each of the plurality of LEDs 120 may also further include a component for increasing the luminous efficiency of each of the plurality of LEDs 120.

According to the embodiment described above with reference to FIGS. 3 to 8, the luminous efficiency of the plurality of LEDs 120 may be further improved by effectively using the pixel electrode, the reflective layer 126, and the insulating layer 127 even though the light-emitting layer 123 is disposed to be perpendicularly to the light-emitting surface.

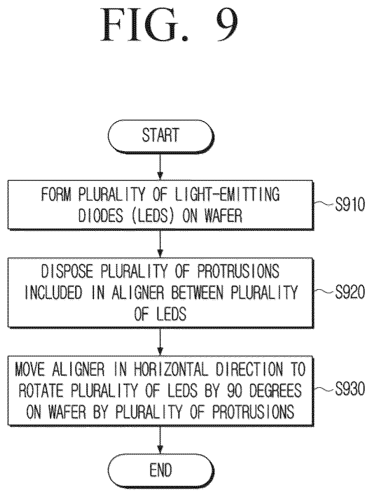

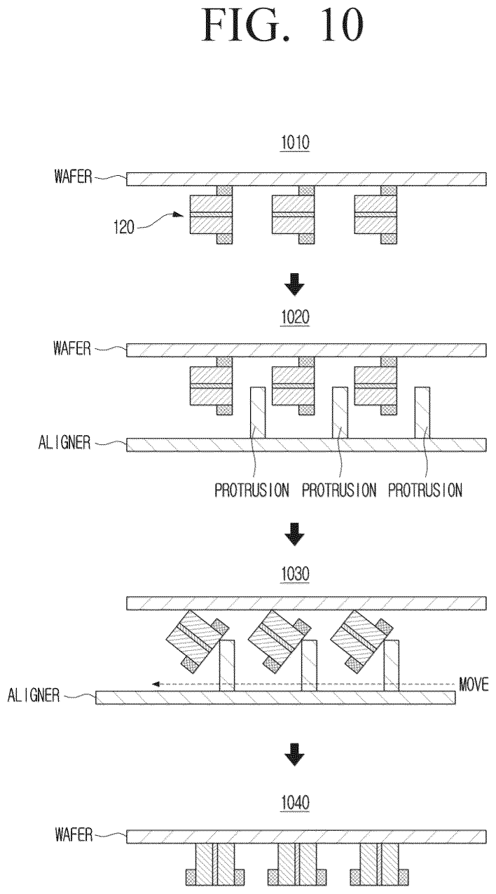

FIG. 9 is a flowchart briefly showing a part of a method of manufacturing a display module 100 according to one or more embodiments of the present disclosure, and FIG. 10 is a view specifically showing a part of the method of manufacturing a display module 100 according to one or more embodiments of the present disclosure.

As shown in FIG. 9, the method of manufacturing a display module 100 may include forming the plurality of LEDs 120 on a wafer (S910). Image 1010 in FIG. 10 shows a state where the plurality of LEDs 120 are formed on the wafer.

In detail, the forming of the plurality of LEDs 120 on the wafer may include depositing the plurality of semiconductor layers on the wafer and forming the two pixel electrodes 124 and 125. As shown in Image 1010 in FIG. 10, in the forming of the two pixel electrodes 124 and 125, the two pixel electrodes 124 and 125 may be formed on the upper right and lower right of the deposited semiconductor layer.

The forming of the plurality of LEDs 120 on the wafer may further include etching some regions of the plurality of LEDs 120. For example, the forming of the plurality of LEDs 120 on the wafer may include etching each of the plurality of LEDs 120 to have the cross-section formed in the inverted trapezoid, as shown in FIG. 2. However, there is no particular limitation on the method of manufacturing the plurality of LEDs 120 itself in the present disclosure.

The method of manufacturing a display module 100 may include disposing a plurality of protrusions included in an aligner between the plurality of LEDs 120 (S920). Here, the “aligner” refers to a component including the plurality of protrusions to rotate the plurality of LEDs 120 by 90 degrees.

In detail, the disposing of the plurality of protrusions included in the aligner may include moving the aligner to the left or right to allow the plurality of protrusions included in the aligner to be oriented between the plurality of LEDs 120 and moving the aligner up or down to allow the uppermost portion of the plurality of protrusions to be disposed to be higher than the lowermost portion of the plurality of LEDs 120.

Image 1020 in FIG. 10 shows a state where the plurality of protrusions included in the aligner are disposed between the plurality of LEDs 120. As shown in Image 1020 in FIG. 10, a spacing between the plurality of protrusions may correspond to a spacing between the plurality of LEDs 120. Meanwhile, there is no particular limitation on how far the plurality of protrusions may be moved upwards as long as the rotation of the plurality of LEDs 120 may be performed smoothly in step S930 described below.

For example, as shown in Image 1020 in FIG. 10, the uppermost portion of the plurality of protrusions may be disposed at a height corresponding to that of the light-emitting layer 123 of the plurality of LEDs 120. In another example, the uppermost portion of the plurality of protrusions may be disposed at a height corresponding to that of the pixel electrode closer to the aligner among the two pixel electrodes 124 and 125 included in the plurality of LEDs 120.

The method of manufacturing a display module 100 may include moving the aligner in the horizontal direction to rotate the plurality of LEDs 120 by 90 degrees on the wafer by the plurality of protrusions (S930). Image 1030 in FIG. 10 shows a state where the plurality of LEDs 120 are rotated while the aligner is moved in the horizontal direction, and Image 1040 in FIG. 10 shows a result of the plurality of LEDs 120 being rotated as the aligner is moved in the horizontal direction

In detail, the plurality of LEDs 120 may be rotated clockwise by 90 degrees if the aligner is moved horizontally while the plurality of protrusions are disposed between the plurality of LEDs 120. Here, whether the horizontal direction in which the aligner is moved is oriented to the left or right may be determined by a transfer process described below. For example, the display module 100 described with reference to FIGS. 1 to 8 may be manufactured if the method includes a process of transferring the LEDs 120 to an intermediate board and then transferring the LEDs 120 to the circuit board 110 even if the aligner is moved to the right, as opposed to what is shown in FIG. 10, to rotate the plurality of LEDs 120 counterclockwise by 90 degrees.

According to the embodiments described above with reference to FIGS. 9 and 10, the plurality of LEDs 120 may be manufactured by stacking the plurality of semiconductor layers on the wafer in the vertical direction and forming the pixel electrodes sequentially above and below the plurality of semiconductor layers, and the plurality of LEDs 120 may then be rotated by 90 degrees using the aligner, thereby forming the arrangement relationship between the plurality of LEDs 120 for manufacturing the display module 100 according to the present disclosure.

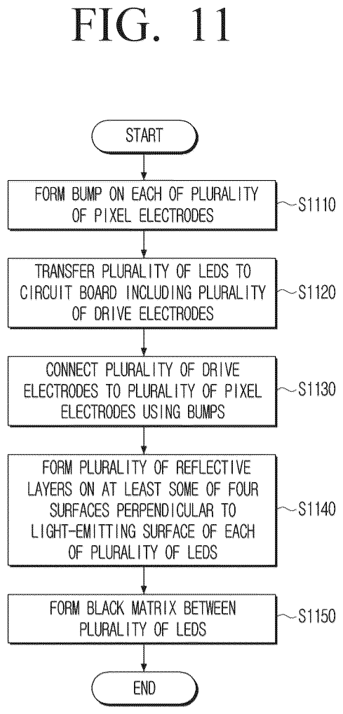

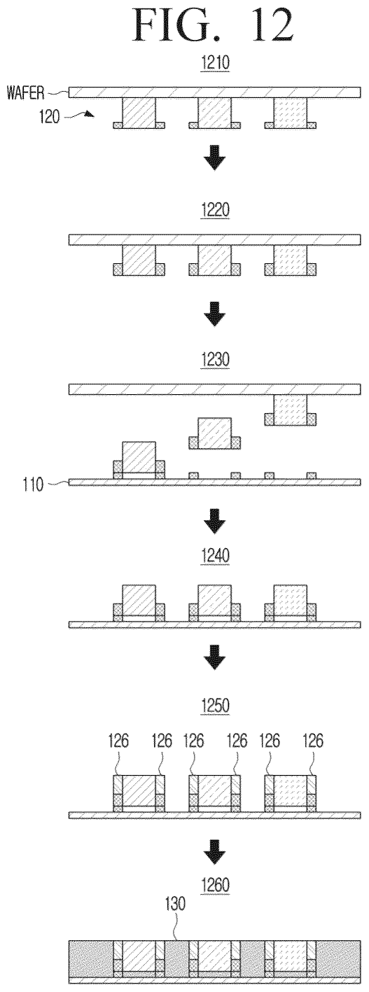

FIG. 11 is a flowchart briefly partially showing another part of the method of manufacturing a display module 100 according to one or more embodiments of the present disclosure, and FIG. 12 is a view specifically showing another part of the method of manufacturing a display module 100 according to one or more embodiments of the present disclosure.

Referring to FIGS. 9 and 10, the description above describes the method of manufacturing the plurality of LEDs 120 and the method of rotating the LEDs 120 as parts of manufacturing a display module 100, and referring to FIGS. 11 and 12, the description describes steps that may be performed after the steps described with reference to FIGS. 9 and 10.

The method of manufacturing a display module 100 may include forming a bump on each of the plurality of pixel electrodes 124 and 125 (S1110). Image 1210 in FIG. 12 shows a state before the bump is formed on each of the plurality of pixel electrodes 124 and 125, and Image 1220 in FIG. 12 shows the state after the bump is formed on each of the plurality of pixel electrodes 124 and 125.

In detail, the “bump” refers to a component for connection between each of the plurality of pixel electrodes 124 and 125 and the drive electrode of the circuit board 110. The bump may be made of a material such as solder alloy or copper, and may be formed using electroplating or the like. There is no particular limitation on the material or formation method of the bump.

The method of manufacturing a display module 100 may include transferring the plurality of LEDs 120 to the circuit board 110 including the plurality of drive electrodes 111 and 112 (S1120). Image 1230 in FIG. 12 shows a process of transferring the plurality of LEDs 120 to the circuit board 110.

The transferring of the plurality of LEDs 120 to the circuit board 110 may also include transferring the plurality of LEDs 120 to at least one motherboard and transferring the plurality of LEDs 120 transferred to the motherboard to the circuit board 110. Here, the motherboard may include a catch agent (e.g., N,N′-Di-n-butyl-1,4-phenylenediamine (NDBR) or polydimethylsiloxane (PDMS)) to capture the plurality of LEDs 120.

The method of manufacturing a display module 100 may include connecting the plurality of drive electrodes 111 and 112 to the plurality of pixel electrodes 124 and 125 using the bumps (S1130) such that they are in contact. Image 1240 in FIG. 12 shows a process of connecting each of the plurality of drive electrodes 111 and 112 to each of the plurality of pixel electrodes 124 and 125 while the plurality of LEDs 120 are transferred to the circuit board 110.

In detail, the connecting of each of the plurality of drive electrodes 111 and 112 to each of the plurality of pixel electrodes 124 and 125 may include a reflow step of heating the circuit board 110 to which the plurality of LEDs 120 are transferred using a reflow oven. If the circuit board 110 to which the plurality of LEDs 120 are transferred is heated, the bump may melt, thus forming an electrical connection between each of the plurality of drive electrodes 111 and 112 and each of the plurality of circuit electrodes, and the bump may then solidify again, thus stabilizing the electrical connection.

The method of manufacturing a display module 100 may include forming the plurality of reflective layers 126 on at least some of the four surfaces perpendicular to the light-emitting surface of each of the plurality of LEDs 120 (S1140). Image 1250 in FIG. 12 shows a state where the reflective layers 126 are formed on the two first surfaces parallel to the plurality of semiconductor layers among the four surfaces perpendicular to the light-emitting surface of each of the plurality of LEDs 120.

In detail, the plurality of reflective layers 126 may be formed during the manufacture of the plurality of LEDs 120, and may also be formed after the manufacture of the plurality of LEDs 120 and the transfer of the plurality of LEDs 120, as described with reference to FIGS. 11 and 12. As an example, FIG. 12 shows that the reflective layers 126 are formed on the two first surfaces parallel to the plurality of semiconductor layers among the four surfaces perpendicular to the light-emitting surface of each of the plurality of LEDs 120. However, as described with reference to FIGS. 3 to 8, there is no particular limitation on the location and number of the plurality of reflective layers 126.

The method of manufacturing a display module 100 may include forming a black matrix 130 between the plurality of LEDs 120 (S1150). Image 1260 in FIG. 12 shows a state where the black matrix 130 fills a space between the plurality of LEDs 120. The black matrix 130 may prevent light interference between the pixels or sub-pixels of the display module 100.

The embodiments related to the method for manufacturing a display module 100 are described above with reference to FIGS. 9 to 12, and the present disclosure is not limited thereto. That is, if the corresponding method is capable of manufacturing the display module 100 described with reference to FIGS. 1 to 8, the method may further include another step in addition to the steps described with reference to FIGS. 9 to 12, or omit some of the steps described with reference to FIGS. 9 to 12.

FIG. 13 is a view showing the electronic device including the display module according to the present disclosure.

As shown in FIG. 13, the electronic device according to the present disclosure may include the display module 100, a memory 200, and the processor 300. However, the configuration shown in FIG. 13 is only an example, and a new component such as a communication device, an input device, or an output device may be added to the configuration shown in FIG. 13, or some components may be omitted to practice the present disclosure.

The display module 100 refers to a component capable of displaying the image, and may have a structure according to the various embodiments described with reference to FIGS. 1 to 12 in particular. That is, the various embodiments described above with reference to FIGS. 1 to 12 may be similarly applied to the display module 100 included in the electronic device.

The memory 200 may store at least one instruction related to the electronic device. In addition, the memory 200 may store an operating system (O/S) for driving the electronic device. In addition, the memory 200 may also store various software programs or applications for operating the electronic device according to the various embodiments of the present disclosure. In addition, the memory 200 may include a semiconductor memory such as a flash memory, or a magnetic storing medium such as a hard disk.

In detail, the memory 200 may store various software modules for operating the electronic device according to the various embodiments of the present disclosure, and the processor 300 may control the operation of the electronic device by executing the various software modules stored in the memory 200. That is, the memory 200 may be accessed by the processor 300, and the processor 300 may perform readout, recording, correction, deletion, update, and the like of data in the memory 200.

Meanwhile, in the present disclosure, the term “memory 200” may be used to indicate the memory 200, a read-only memory (ROM) or a random access memory (RAM) within the processor 300, or the memory card mounted in the electronic device.

In one or more embodiments, the memory 200 may store image data and an instruction for displaying the image on the display module 100 based on the image data. In addition, the memory 200 may store various information required within a scope to achieve the purpose of the present disclosure, and the information stored in the memory 200 may be updated as the information is received from an external device or input by a user.

The processor 300 may control overall operations of the electronic device. In detail, the processor 300 may be connected to the components of the electronic device including the display module 100 and the memory 200, and control the overall operations of the electronic device by executing at least one instruction stored in the memory 200 as described above.

The processor 300 may be implemented in various ways. For example, the processor 300 may be implemented as at least one of an application-specific integrated circuit, the embedded processor, the microprocessor, hardware control logic, a hardware finite state machine, or the digital signal processor. Meanwhile, in the present disclosure, the term “processor 300” may be used to indicate a central processing unit (CPU), a graphics processing unit (GPU), or a microprocessor unit (MPU).

In one or more embodiments, the processor 300 may control the display module 100 to display the image based on the image data stored in the memory 200. In detail, the processor 300 may include at least one timing controller for controlling the driving of the plurality of LEDs 120 and a panel driver for controlling the driving of the display panel.

The timing controller may control the panel driver to control the plurality of LEDs 120. In detail, the timing controller may adjust the image data stored in the memory 200 to a signal required by the panel driver, and transmit the adjusted signal to the panel driver to allow the panel driver to control the driving of the plurality of LEDs 120.

The panel driver may control the driving of the plurality of LEDs 120 based on the signal received from the timing controller. For example, the panel driver may include a plurality of drive integrated circuits (ICs) and a plurality of pixel drive circuits. In addition, the plurality of driving ICs may control the light emission of a plurality of light-emitting devices included in the plurality of LEDs 120 respectively connected to the plurality of pixel drive circuits by driving the plurality of pixel drive circuits.

In one or more embodiments, the processor 300 may adjust the control signal for driving the plurality of LEDs to suit the structure of the display module according to the embodiments described above with reference to FIGS. 1 to 8.

Each component (e.g., module or program) according to the various embodiments of the present disclosure described above may include a single entity or a plurality of entities, and some of the corresponding sub-components described above may be omitted or other sub-components may be further included in the various embodiments. Alternatively or additionally, some of the components (e.g., modules or programs) may be integrated into the single entity, and may perform functions performed by the respective corresponding components before being integrated in the same or similar manner.

Operations performed by the modules, the programs, or other components according to the various embodiments may be executed in a sequential manner, a parallel manner, an iterative manner or a heuristic manner, at least some of the operations may be performed in a different order or be omitted, or other operations may be added.

Although the embodiments of the present disclosure are shown and described as above, the present disclosure is not limited to the above-mentioned specific embodiments, and may be variously modified by those skilled in the art to which the present disclosure pertains without departing from the gist of the present disclosure as claimed in the accompanying claims. These modifications should also be understood to fall within the scope and spirit of the present disclosure.

What is claimed is:

1. A display comprising:
a circuit board comprising a first drive electrode and a second drive electrode; and
a light-emitting diodes (LED) comprising:
semiconductor layers stacked in a horizontal direction parallel to a surface of the circuit board, the semiconductor layers comprising:
an n-type semiconductor layer;
a light-emitting layer; and
a p-type semiconductor layer;
a first pixel electrode in contact with the first drive electrode; and
a second pixel electrode in contact with the second drive electrode.

2. The display as claimed in claim 1, wherein the LED further comprises:
a light-emitting surface parallel to the surface of the circuit board; and
reflective layers on at least two of four side surfaces of the LED and perpendicular to the light-emitting surface.

3. The display as claimed in claim 2, wherein the first pixel electrode and the second pixel electrode are on two first side surfaces parallel to the semiconductor layers among the four side surfaces, and
wherein the reflective layers are on two second side surfaces perpendicular to the semiconductor layers among the four side surfaces.

4. The display as claimed in claim 2, wherein the reflective layers are on the four side surfaces and on a lower surface of the LED.

5. The display as claimed in claim 2, wherein the LED further comprises an insulating layer on a lower surface of the LED.

6. The display as claimed in claim 3, wherein the first pixel electrode and the second pixel electrode are in contact with portions of lower regions of the two first side surfaces.

7. The display as claimed in claim 6, wherein the first pixel electrode and the second pixel electrode contact two of vertices of a square corresponding to one of the two second side surfaces.

8. The display as claimed in claim 1, wherein an area of an upper surface of the LED corresponding to a light-emitting surface is greater than an area of a lower surface of the LED.

9. A light-emitting diode (LED) comprising:
a light-emitting surface;
a light-emitting layer;
a p-type semiconductor layer stacked on a first side of the light-emitting layer in a direction parallel to the light-emitting surface;
an n-type semiconductor layer stacked on a second side opposite the first side of the light-emitting layer in the direction parallel to the light-emitting surface;
a first pixel electrode connected to the p-type semiconductor layer; and
a second pixel electrode connected to the n-type semiconductor layer.

10. The LED as claimed in claim 9, further comprising:
reflective layers on at least two of four side surfaces of the LED and perpendicular to the light-emitting surface.

11. The LED as claimed in claim 10, wherein the first pixel electrode and the second pixel electrode are on two first side surfaces parallel to the light-emitting layer among the four side surfaces, and
wherein the reflective layers are on two second side surfaces perpendicular to the light-emitting layer among the four side surfaces.

12. The LED as claimed in claim 10, wherein the reflective layers are on the four side surfaces and on a lower surface of the LED.

13. The LED as claimed in claim 10, further comprising:
an insulating layer on a lower surface of the LED.

14. The LED as claimed in claim 11, wherein the first pixel electrode and the second pixel electrode are in contact with portions of lower regions of the two first side surfaces.

15. The LED as claimed in claim 14, wherein the first pixel electrode and the second pixel electrode contact two of vertices of a square corresponding one of the two second side surfaces.

16. The LED as claimed in claim 9, wherein an area of an upper surface of the LED corresponding to the light-emitting surface is greater than an area of a lower surface of the LED.

17. The display as claimed in claim 1, further comprising a plurality of the LED.
